(19) United States
(12) Patent Application Publication
(10) Pub. No.: US 2011/0109776 A1
(43) Pub. Date: May 12, 2011

(54) IMAGING DEVICE AND IMAGING APPARATUS

(75) Inventor: Tomoyuki KAWAI, Tokyo (JP)

(73) Assignee: FUJIFILM CORPORATION, Tokyo (JP)

(21) Appl. No.: 12/942,387

(22) Filed: Nov. 9, 2010

(30) Foreign Application Priority Data
Nov. 10, 2009 (JP) 2009-257122

(51) Int. Cl. H04N 5/335; H01L 27/146

(52) U.S. Cl. 348/273; 250/208.1; 348/294; 348/E05.091

(57) ABSTRACT

An imaging device includes a plurality of pixels each of which includes a microlens, first and second photoelectric conversion portions. The first photoelectric conversion portion is between the microlens and a focal point of the microlens. The second photoelectric conversion portion is at a position being different from that of the focal point on a plane which is parallel to an imaging plane and which contains the focal point, and has a photoelectric conversion region deviated from an optical axis of the microlens in a direction of the imaging plane. The plurality of pixels includes a first pixel group and a second pixel group. The photoelectric conversion region is deviated from the optical axis in the direction in the first pixel group. The photoelectric conversion region is deviated from the optical axis in the direction to be opposite to the first pixel group in the second pixel group.

### CROSS-REFERENCE TO RELATED APPLICATIONS

This application claims the benefit of Japanese Patent Application No. 2009-257122, filed on Nov. 10, 2009, the entire contents of which are hereby incorporated by reference, the same as if set forth at length; the entire of which are incorporated herein by reference.

### BACKGROUND OF THE INVENTION

1. Technical Field

The present invention relates to an imaging device and an imaging apparatus.

2. Description of Related Art

A contrast detection method and a pupil division type phase difference detection method have been known as methods for performing autofocus (AF) in an imaging apparatus such as a digital camera.

The contrast detection method can utilize an imaging device for a recording image. However, it is necessary to capture a plurality of images by shifting a focal point. Accordingly, the contrast detection method has a disadvantage in low AF speed.

On the other hand, the pupil division type phase difference detection method can increase an AF speed, because a sensor for detecting a phase difference is provided separately from a sensor for a recording image. However, the pupil division type phase difference detection method is disadvantageous in large size and high cost of an imaging apparatus.

JP-A-2000-156823 describes a technique for deviating the position of a photodiode of each pixel of a part of a plurality of pixels arranged on an imaging plane from an associated microlens thereof to thereby cause each of such pixels to function as a phase difference sensor.

JP-A-2008-085160 relates to an imaging device that has a plurality of photoelectric conversion elements arranged on a surface of a semiconductor substrate, a photoelectric conversion layer having light sensitivity to light of infrared wavelengths, which is provided above the semiconductor substrate, and a color filter layer provided above the photoelectric conversion layer. This imaging device obtains color image data and infrared image data by performing imaging once.

As described in JP-A-2000-156823, if a partial region of an imaging plane as a region for detecting a phase difference, there is no necessity for separately providing a phase difference sensor. However, in this case, AF operation can be performed only at angles within a part of an angle of view of a recording image. In addition, an image configured by pixels corresponding to this region is unsuited as a recording image. Thus, the image-quality of a recording image is considered to be degraded.

The imaging device described in JP-A-2008-85160 is such that the photoelectric conversion layer provided above the semiconductor substrate has sensitivity to infrared light and that the photoelectric conversion element performs photoelectric conversion on light having wavelengths differing from those of the infrared light.

Hitherto, there has been no apparatus that generates signal electric charges for a recording image, and signal electric charges for phase difference AF, using light of the same wavelength.

An object of the invention is to provide an imaging device and an image apparatus, which can simultaneously perform the imaging of a recording image and the detection of a phase difference, and can also perform AF on the entire recording image and prevent the deterioration of the recording image.

### SUMMARY

An imaging device includes a plurality of two-dimensionally-arranged pixels each of which generates signal electric charges by performing photoelectric conversion of incident light. Each of the pixels includes a microlens, a first photoelectric conversion portion, a second photoelectric conversion portion and a signal reading portion. The microlens collects incident light. The first photoelectric conversion portion is between the microlens and a focal point of the microlens. The second photoelectric conversion portion is at a position being different from a position of the focal point on a plane which is parallel to an imaging plane and which contains the focal point. The second photoelectric conversion portion has a photoelectric conversion region deviated from an optical axis of the microlens in a direction of the imaging plane. The signal reading portion reads a signal electric charge. The plurality of pixels include a first pixel group and a second pixel group. The photoelectric conversion region of the second photoelectric conversion portion is deviated from the optical axis in the direction of the imaging plane in the first pixel group. The photoelectric conversion region of the second photoelectric conversion portion is deviated from the optical axis in the direction of the imaging plane to be opposite to the first pixel group in the second pixel group

An imaging device includes a plurality of two-dimensionally-arranged pixels each of which generates signal electric charges by performing photoelectric conversion of incident light. Each of the pixels includes a microlens, a first photoelectric conversion portion, a second photoelectric conversion portion and a signal reading portion. The microlens collects incident light. The first photoelectric conversion portion is between the microlens and a focal point of the microlens. The second photoelectric conversion portion is at a position being different from a position of the focal point on a plane which is parallel to an imaging plane and which contains the focal point. The signal reading portion reads a signal electric charge. The second photoelectric conversion portion has a plurality of photoelectric conversion regions formed to be deviated from the optical axis in different orientations on the imaging plane to be symmetric with respect to a center of the optical axis of the microlens.

An imaging apparatus includes the above imaging device and a unit. The unit generates a recording image based on a signal electric charge obtained from the first photoelectric conversion portion, detects a phase difference and computes a focal point based on a signal electric charge obtained from the second photoelectric conversion portion.

In the imaging device, signal electric charges for a recording image are generated in the first photoelectric conversion. And, signal electric charges for detecting a focal point are generated in response to the direction in which the photoelectric conversion region of the second photoelectric conversion portion are deviated from the optical axis in the first and second pixel group of the second photoelectric conversion which is the same position on the imaging plane with respect to the first photoelectric conversion. The imaging device can detect a phase difference based on signal electric charges of the first and second pixel group respectively. The imaging device can control a focused state and a D-focus amount based on the phase difference. The imaging device can simultaneously perform the imaging of a recording image and the detection of a phase difference because the first and second photoelectric conversions are provided in each pixel of the plurality of the pixels. Further, the imaging device can perform AF on the entire recording image and prevent the deterioration of the recording image.

In the structure of the photoelectric conversion layer provided above the semiconductor substrate as shown in JP-A-2008-085160, a part of the incident light transmits through the photoelectric conversion layer while the incident light attenuates in response to a thickness and absorption coefficient of the photoelectric conversion layer. The imaging device can utilize the incident light transmitted through the photoelectric conversion layer by performing the photoelectric conversion in the second photoelectric conversions of each pixel to generate the signal electric charges for phase difference AF.

The invention can provide an imaging device and an image apparatus, which can simultaneously perform the imaging of a recording image and the detection of a phase difference, and can also perform AF on the entire recording image and prevent the deterioration of the recording image.

### BRIEF DESCRIPTION OF THE DRAWINGS

FIG. 1 is a cross-sectional view illustrating an imaging device.

FIG. 2 is a view illustrating the positional relationship between a photoelectric conversion region of a photoelectric conversion film and that of a photodiode.

FIG. 3 is a view illustrating an example of arrangement of pixels.

FIG. 4 is a view illustrating an example of arrangement of pixels.

FIG. 5 is a view illustrating the configuration of a signal reading unit illustrated in FIG. 1.

FIG. 6 is a view illustrating another example of the configuration of an imaging device.

FIG. 7 is a view illustrating the positional relationship between a photoelectric conversion region of a photoelectric conversion film and that of a photodiode in the configuration of the imaging device.

FIG. 8 is a view illustrating another configuration of an imaging device.

FIG. 9 is a view illustrating another configuration of an imaging device.

FIG. 10 is a view illustrating an imaging apparatus.

### DETAILED DESCRIPTION OF EMBODIMENTS OF THE INVENTION

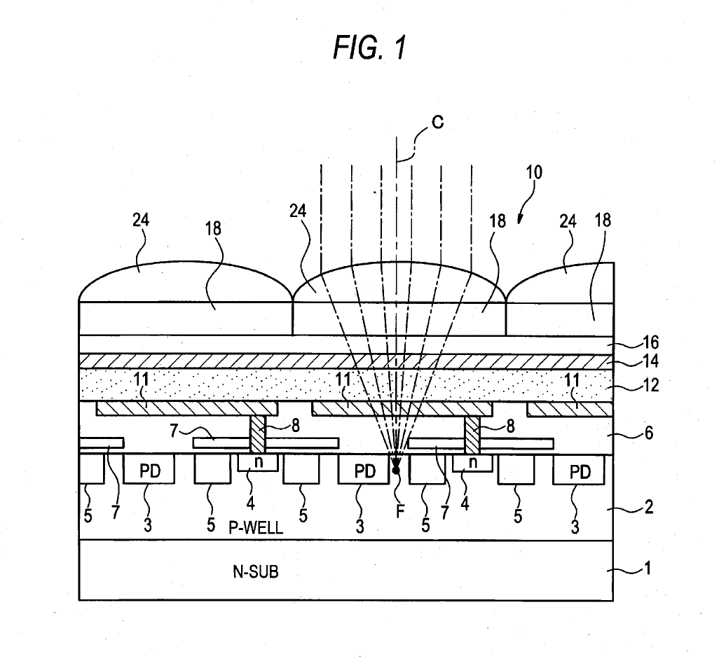

FIG. 1 is a cross-sectional view illustrating an imaging device. An imaging device 10 has a semiconductor substrate that is an n-type silicon substrate 1 on which a p-well layer 2 is formed. FIG. 1 illustrates a state in which a light-incidence-side of the imaging device 10 is set to be an upper side. Thus, in the following description made with reference to FIG. 1, the direction of the light-incidence-side of the imaging device 10 is assumed to be an “upper” direction or a “top direction”. The opposite direction of the light-incidence-side is assumed to be a “lower” direction or a “bottom direction”.

Embedded type photodiodes 3, n-type impurity diffused regions 4, and signal reading portions 5 are provided in the p-well layer 2. The signal reading portions 5 are provided respectively corresponding to each photodiode 3 and each impurity diffused region 4 one-by-one.

A transparent insulating film 6 is provided on the p-well layer 2. A plurality of pixel electrodes 11 are provided on the top surface of the insulating film 6 such that the plurality of pixel electrodes 11 and the top surface of the insulating film 6 form the same plane. The pixel electrodes 11 are configured by an electrode material, such as indium tin oxide (ITO), transparent to visible light.

Columnar contact portions 8 are provided in the insulating film 6 to extend in the thickness direction of the insulating film 6. The top part of each contact portion 8 is connected to an associated one of the pixel electrodes 11. The bottom part of each contact portion 8 is connected to an associated one of the impurity diffused regions 4 provided in a surface of the p-well layer 2 of the semiconductor substrate. The contact portions 8 can be subjected to insulating processing so as not to electrically communicate with parts other than the pixel electrodes 11 and the impurity diffused regions 4. For example, processing configured by forming a slight gap between each contact portion 8 and another electrically conductive material and filling the gap with an insulating material can be cited as the insulating processing.

Light shielding films 7 made of materials, such as tungsten, having a light shielding property to visible light are formed in the insulating film 6. Each light shielding film 7 is opened at a place in an upper direction of the photodiodes 3. The impurity diffused regions 4 and the signal reading portion 5 are covered with the light shielding films 7 from above. Thus, regions of the semiconductor substrate other than the photodiodes 3 are shielded from light.

A photoelectric conversion film 12 configured by a single layer is formed to cover the top surface of each of the insulating film 6 and the pixel electrodes 11. The photoelectric conversion film 12 employs a photoelectric conversion material configured by an organic material and amorphous silicon. The photoelectric conversion film 12 generates signal electric charges by performing the photoelectric conversion of incident light. What is called a panchromatic film having sensitivity to the entire range of wavelengths of visible light is used as the photoelectric conversion film 12. The photoelectric conversion film 12 performs the photoelectric conversion of about 70% of incident light. About remaining 30% of incident light is transmitted by the photoelectric conversion film 12.

A counter electrode 14 configured by a single layer is provided on the photoelectric conversion film 12. The counter electrode 14 is configured by an electrode material, such as ITO, which is transparent to visible light similar to the pixel electrodes 11.

A protection film 16 is provided on the counter electrode 14. A plurality of color filters 18 are arranged on the protection film 16. Each of the plurality of color filters 18 is such that an R-color filter transmitting light of a red wavelength range, a G-color filter transmitting light of a green wavelength range, and a B-color filter transmitting light of a blue wavelength range are arranged in a Bayer array. The arrangement of the color filters 18 is not limited to the Bayer array.

A microlens 24 for collecting incident light is provided on each color filter 18.

The imaging device 10 has a plurality of two-dimensionally-arranged pixels in a case where the pixels are assumed to be arranged on a two-dimensional plane parallel to a horizontal direction, as viewed in FIG. 1. The pixels include the single photodiode 3, the pixel electrode 11 provided in an upper direction of the photodiode 3, and the regions of the photoelectric conversion film 12 on the pixel electrode 11 and the counter electrode 14. In addition, the pixels include the single color filter 18 and the signal microlens 24 provided above the pixel electrode 11. Besides, the pixels include the signal reading portion 5 for reading signal electric charges. FIG. 1 illustrates three pixels adjoining one another among a plurality of pixels.

Alternate long and short dash lines illustrated in FIG. 1 represent the incident light, and the optical paths of light collected by the microlens 24. Reference character F in FIG. 1 designates a focal point of the microlens 24. Reference character C in FIG. 1 designates an optical axis of the microlens 24. The optical axis C is a straight line which passes through the center of the microlens 24 and intersects with a light flux collected by the microlens 24 at the focal point F.

The imaging device 10 is such that the photoelectric conversion film 12 of each pixel is provided between the microlens 24 thereof and the focal point F thereof. The photodiode 3 is provided at a position being different from a position of the focal point F of the microlens 24 on a plane which is parallel to an imaging plane and which contains the focal point F. In addition, the photodiode 3 has a photoelectric conversion region deviated from the optical axis C in a direction of the imaging plane. The photoelectric conversion region of the photodiode 3 corresponds to an opened region of the light shielding film 7. That is, the opening of the light shielding film 7 is provided at a position deviated from the optical axis C of the microlens 24.

In this example of the imaging device 10, the photoelectric conversion film 12 functions as a first photoelectric conversion portion that generates signal electric charges for a recording image. The photodiode 3 functions as a second photoelectric conversion portion that generates signal electric charges for phase difference AF.

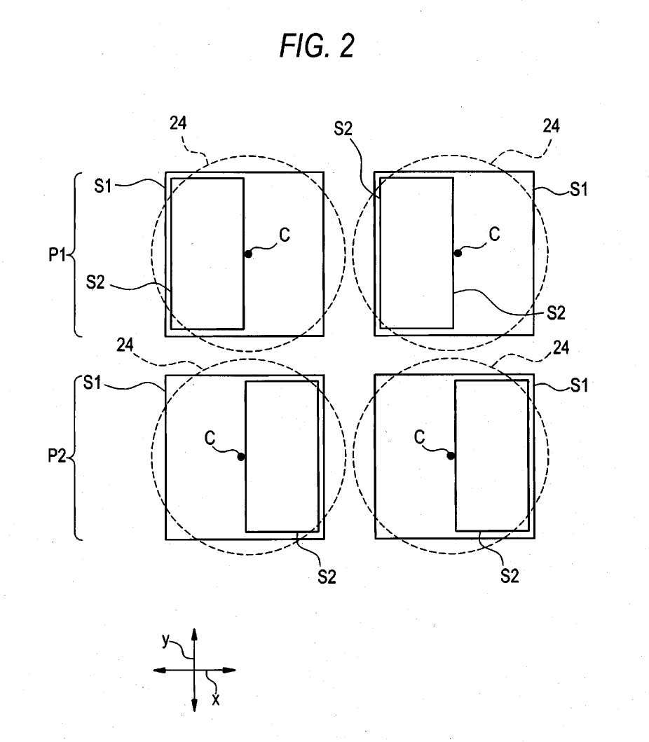

FIG. 2 is a view illustrating the positional relationship between the photoelectric conversion region of the photoelectric conversion film and that of the photodiode. FIG. 2 illustrates a state taken from a direction perpendicular to a plane (imaging plane) on which a plurality of pixels are arranged. The configuration of the imaging device 10 described with reference to FIG. 1 is arbitrarily referred to below. FIG. 2 illustrates the photoelectric conversion region of each of four pixels arranged on a two-dimensional plane represented by coordinates respectively corresponding to arrows x and y. It is assumed that the direction indicated by the arrow x is a horizontal direction of the imaging plane of the imaging device, and that the direction indicated by the arrow y is a vertical direction of the imaging plane thereof.

Reference numeral S1 in FIG. 2 designates a photoelectric conversion region of the photoelectric conversion film 12. Referring to FIG. 1, the photoelectric conversion region S1 of the photoelectric conversion film 12 corresponds to a zone sandwiched between the pixel electrode 11 and the counter electrode 14 in each pixel in the photoelectric conversion film 12. The position of the center of the photoelectric conversion region S1 of the photoelectric conversion film 12 substantially coincides with that of the optical axis C of the microlens 24.

Reference numeral S2 in FIG. 2 designates a photoelectric conversion region of the photodiode 3. Referring to FIG. 1, the photoelectric conversion region S2 corresponds to a zone in the photodiode 3, in which a signal electric charge is generated through photoelectric conversion by causing light passing through an opening of the light shielding film 7 to be incident thereon. The photoelectric conversion region S2 of the photodiode 3 is determined by the position of the opening of the light shielding film 7. The photoelectric conversion region S2 of the photodiode 3 is deviated from the optical axis C of the microlens 24.

In the example illustrated in FIG. 2, a plurality of pixels include a first pixel group P1 of pixels each of which has the photodiode 3, whose photoelectric conversion region S2 is deviated in one of the orientations of the horizontal direction x from the optical axis C, and a second pixel group P2 of pixels each of which has the photodiode 3, whose photoelectric conversion region S2 is deviated in the other orientation of the horizontal direction x from the optical axis C. The photoelectric conversion region S2 of each photodiode 3 of the first pixel group P1 and that S2 of each photodiode 3 of the second pixel group P2 are respectively deviated in the different orientations of the horizontal direction x from the optical axis C. The photoelectric conversion region S2 of each photodiode 3 of the first pixel group P1 and that S2 of each photodiode 3 of the second pixel group P2 are in symmetrical position relation with respect to the optical axis C.

The photoelectric conversion film 12 of each pixel performs photoelectric conversion of incident light to generate signal electric charges for a recording image. The photodiode 3 performs photoelectric conversion of a part of light transmitted by the photoelectric conversion film 12 to generate signal electric charges for phase difference AF. At that time, a phase difference can be detected according to signal electric charges generated by the photodiode 3 by setting the horizontal direction x as a pupil division direction.

As a configuration other than that illustrated in FIG. 2, the first pixel group P1 and the second pixel group P2 can be configured so that the photoelectric conversion region S2 of the photodiode 3 of each pixel of the first pixel group P1 and that S2 of the photodiode 3 of each pixel of the second pixel group P2 are respectively deviated from the optical axis C in the different orientations of the vertical direction y. In this case, a phase difference is detected according to signal electric charges generated by the photodiode 3 by setting the vertical direction y as the pupil division direction.

Preferably, each pixel of each of the first pixel group P1 and the second pixel group P2 in the arrangement of pixels illustrated in FIG. 2 includes a G-color filter transmitting light of a green wavelength range. With this arrangement, signal electric charges for phase difference AF obtained from each pixel of each of the first pixel group P1 and the second pixel group P2 are output from the G-color filter, similarly. Thus, the accuracy of detection of a phase difference can be enhanced.

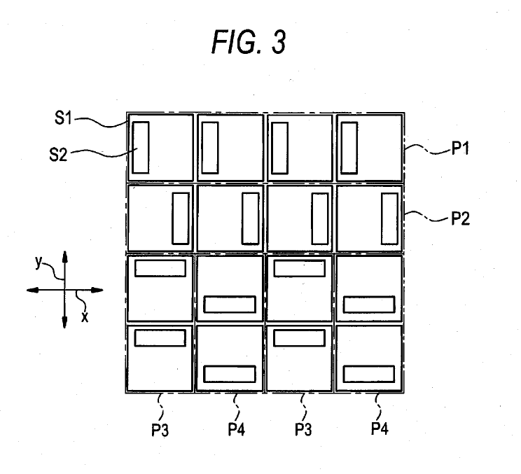

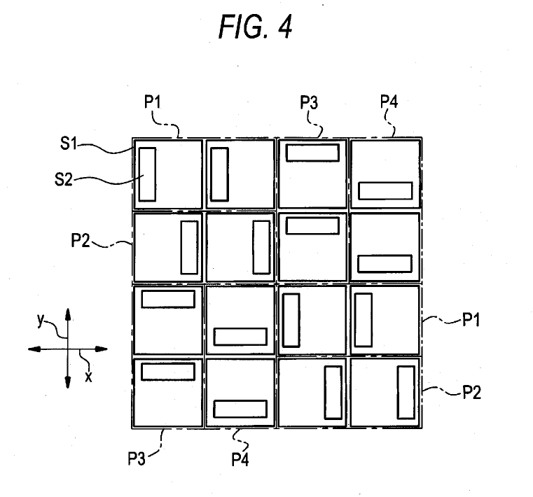

FIGS. 3 and 4 illustrate examples of the arrangement of pixels. In the following examples, a plurality of pixels further includes a third pixel group P3 and a fourth pixel group P4, in addition to the first pixel group P1 and the second pixel group P2. Each pixel has the same configuration, except for the positional relationship among the photodiode 3 and the other components.

According to the arrangement of the example illustrated in FIG. 3, in each pixel of the first pixel group P1 and the second pixel group P2, the photoelectric conversion region S2 of the photodiode 3 is deviated in the horizontal direction x. In each pixel of the third pixel group P3 and the fourth pixel group P4, the photoelectric conversion region S2 of the photodiode 3 is deviated in the vertical direction y. That is, a direction in which the photoelectric conversion region S2 of the photodiode 3 is deviated in each pixel of the third pixel group P3 and the fourth pixel group P4 is perpendicular to that in which the photoelectric conversion region S2 of the photodiode 3 is deviated in each pixel of the first pixel group P1 and the second pixel group P2. In the example illustrated in FIG. 3, a row configured by pixels of the first pixel group P1 and a row configured by pixels of the second pixel group P2 are disposed by being arranged in the vertical direction y. In addition, rows each of which is configured by alternately arranging a pixel of the third pixel group P3 and that of the fourth pixel group P4 in the horizontal direction x are arranged.

With the arrangement of pixels illustrated in FIG. 3, signal electric charges for phase difference AF employing the horizontal direction x as the pupil division direction are obtained by the first pixel group P1 and the second pixel group P2. In addition, signal electric charges for phase difference AF employing the vertical direction y as the pupil division direction are obtained by the third pixel group P3 and the fourth pixel group P4.

According to the arrangement of the example illustrated in FIG. 4, similarly to the arrangement of the example illustrated in FIG. 3, in each pixel of the first pixel group P1 and the second pixel group P2, the photoelectric conversion region S2 of the photodiode 3 is deviated in the horizontal direction x. In each pixel of the third pixel group P3 and the fourth pixel group P4, the photoelectric conversion region S2 of the photodiode 3 is deviated in the vertical direction y. In addition, the direction in which the photoelectric conversion region S2 of the photodiode 3 is deviated in each pixel of the third pixel group P3 and the fourth pixel group P4 is perpendicular to that in which the photoelectric conversion region S2 of the photodiode 3 is deviated in each pixel of the first pixel group P1 and the second pixel group P2. According to the example illustrated in FIG. 4, if an array configured by 2 pixels×2 pixels is set to be 1 block, the arrangement of pixels includes blocks each configured by a row in which two pixels of the first pixel group P1 are arranged in the horizontal direction x, and a row in which two pixels of the second pixel group P2 are arranged in the horizontal direction x, and blocks each configured by a column in which two pixels of the third pixel group P3 are arranged in the vertical direction y, and a column in which two pixels of the fourth pixel group P4 are arranged in the vertical direction y. At that time, each block configured by pixels of the third pixel group P3 and the fourth pixel group P4 is arranged to adjoin a block configured by pixels of the first pixel group P1 and the second pixel group P2.

With the arrangement of pixels illustrated in FIG. 4, similarly to the arrangement illustrated in FIG. 3, signal electric charges for phase difference AF employing the horizontal direction x as the pupil division direction are obtained by the first pixel group P1 and the second pixel group P2. In addition, signal electric charges for phase difference AF employing the vertical direction y as the pupil division direction are obtained by the third pixel group P3 and the fourth pixel group P4.

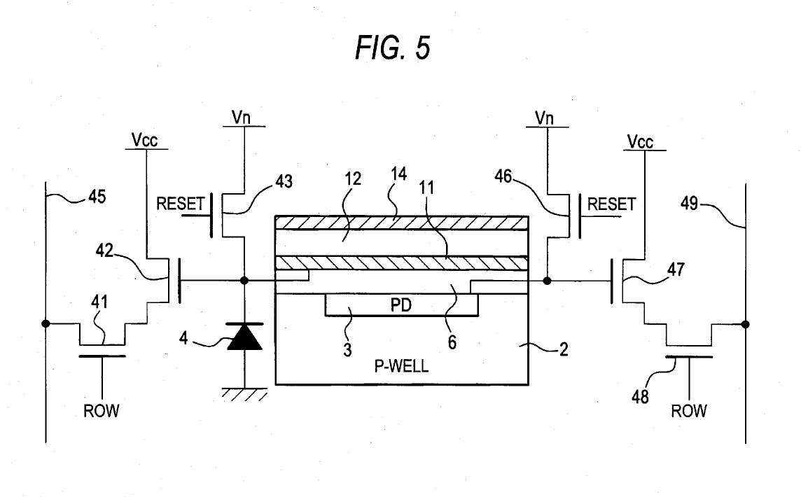

Next, the configuration of the signal reading portion is described hereinafter. FIG. 5 is a view illustrating the configuration of the signal reading portion illustrated in FIG. 1. The signal reading portion 5 is a metal-oxide semiconductor (MOS) circuit having three transistors. The configurations of the signal reading portions 5 in the pixels are the same as one another.

In FIG. 5, each of the same components as those illustrated in FIG. 1 is designated with the same reference numeral. The signal reading portion 5 includes reset transistors 43 and 46, output transistors 42 and 47, and row selection transistors 41 and 48.

The reset transistor 43 is such that the drain thereof is connected to the impurity diffused region 4, and that the source thereof is connected to a power supply Vn.

The output transistor 42 is such that the gate thereof is connected to the drain of the reset transistor 43, and that the source thereof is connected to a power supply Vcc.

The row selection transistor 41 is such that the source thereof is connected to the drain of the output transistor 42 and that the drain thereof is connected to a signal output line 45.

The reset transistor 46 is such that the drain thereof is connected to the photodiode 3, and that the source thereof is connected to the power supply Vn.

The output transistor 47 is such that the gate thereof is connected to the drain of the reset transistor 46, and that the source thereof is connected to the power supply Vcc.

The row selection transistor 48 is such that the source thereof is connected to the drain of the output transistor 47 and that the drain thereof is connected to a signal output line 49.

A bias voltage is applied between the pixel electrode 11 and the counter electrode 14 to thereby generate electric charges in the photoelectric conversion film 12 according to incident light. The electric charges are transferred to the impurity diffused region 4 through the pixel electrode 11 and the contact portion 8. The electric charges stored in the impurity diffused region 4 are converted at the output transistor 42 according to an electric charge amount thereof. Then, the row selection transistor 41 is turned on so that signals are output to the signal output line 45. After the signals are output, the electric charges in the impurity diffused region 4 is reset by the reset transistor 43.

When light transmitted by the photoelectric conversion film 12 is incident on the photodiode 3, electric charges are generated by photoelectric conversion in the photodiode 3. The electric charges generated in the photodiode 3 are converted into signals at the output transistor 47 according to an electric charge amount thereof. Then, the row selection transistor 48 is turned on so that signals are output to the signal output line 49. After the signals are output, electric charge in the photodiode 3 is reset by the reset transistor 46.

Electric charges generated in the photoelectric conversion film 12 and the photodiode 3 are read out by the signal reading portion 5 as signal electric charges separately from each other. Then, the signal electric charges in the photoelectric conversion film 12 are processed as signal electric charges for a recording image. The signal electric charges in the photodiode 3 are processed as signal electric charges for phase difference AF.

According to such the imaging device 10, the photoelectric conversion film 12 and the photodiode 3 are provided in each of a plurality of pixels. Accordingly, the imaging of a recording image and the detection of a phase difference can simultaneously be performed. In addition, phase difference AF can be performed on the entire recording image. Consequently, the recording image can be prevented from being deteriorated.

When performing imaging, a part of incident light is transmitted by the photoelectric conversion film 12 in each pixel. The transmitted light is received by the photodiode 3. Thus, the received light is subjected to photoelectric conversion at the photodiode 3. Accordingly, the photodiode 3 of each pixel generates signal electric charges for phase difference AF, through photoelectric conversion. The imaging device 10 is such that the photoelectric conversion film 12 has sensitivity to the entire range of visible light. The imaging device 10 can generate signal electric charges for a recording image by performing photoelectric conversion of most of incident light. Because light transmitted by the photoelectric conversion film 12 is converted by photoelectric conversion into signal electric charges for phase difference AF, incident light can effectively be utilized.

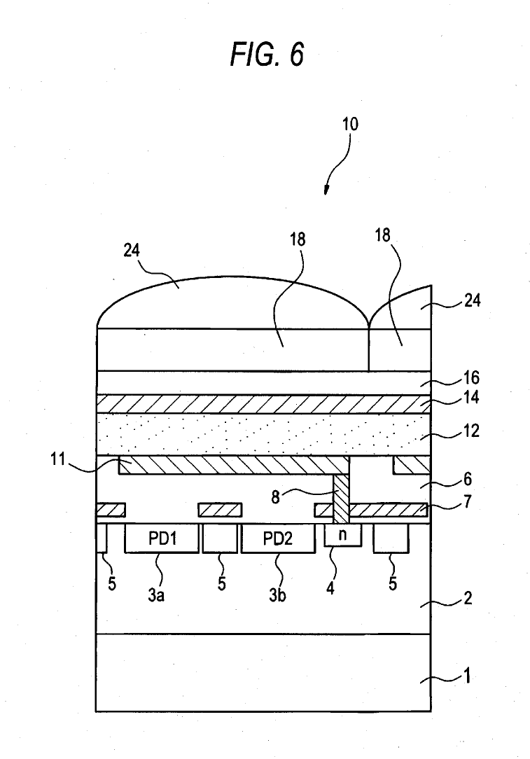

FIG. 6 is a view illustrating another example of the configuration of the imaging device. The configuration of the imaging device illustrated in FIG. 6 is nearly similar to that of the imaging device illustrated in FIG. 1. In the following description, different components provided therebetween are described. The same component as the member which has already been described is designated with the same reference numeral. Thus, the description of such a component is omitted.

The imaging device 10 is such that two embedded type photodiodes 3a and 3b are provided in the p-well layer 2 of the semiconductor substrate of each pixel. The photodiodes 3a and 3b have the same configuration and are equal to each other in impurity concentration and size with respect to the semiconductor substrate. The remaining region of the semiconductor substrate, which is other than the region thereof provided with the photodiodes 3a and 3b, is covered with the shielding film 7 thereby to be shielded from light. Thus, signal electric charges for phase difference AF are generated through photoelectric conversion at each of the photodiodes 3a and 3b by causing a part of light transmitted by the photoelectric conversion film 12 in incident light to be incident on the photodiodes 3a and 3b. In this example, each of the photodiodes 3a and 3b functions as a second photoelectric conversion portion and has a photoelectric conversion region. In this configuration, the signal reading portion 5 for reading signal electric charges from the photodiodes 3a and 3b is provided between the photodiodes 3a and 3b in the p-well 2. A part of the light shielding film 7 is also provided on the signal reading portion 5.

This example is configured so that the two photodiodes 3a and 3b are provided in the semiconductor substrate. However, the number of the photodiodes is not limited to 2. Three or more photodiodes can be provided in the semiconductor substrate.

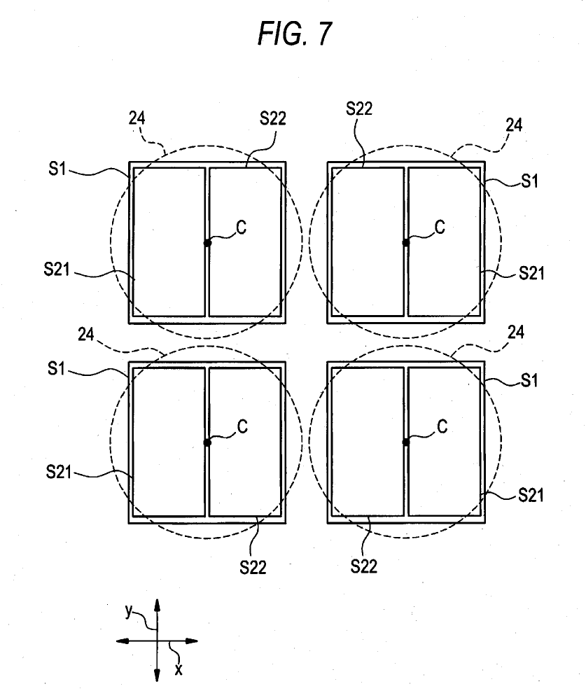

FIG. 7 is a view illustrating the positional relationship between the photoelectric conversion region of the photoelectric conversion film and that of the photodiode in the configuration of the imaging device illustrated in FIG. 6. FIG. 7 illustrates a state in which the photoelectric conversion region of the photoelectric conversion film and that of the photodiode are shown in plan view.

Reference numeral S1 in FIG. 7 designates a photoelectric conversion region of the photoelectric conversion film 12, which corresponds to a zone sandwiched between the pixel electrode 11 and the counter electrode 14 in each pixel in the photoelectric conversion film 12. The position of the center of the photoelectric conversion region S1 of the photoelectric conversion film 12 substantially coincides with that of the optical axis C of the microlens 24.

FIG. 7 illustrates the photoelectric conversion region S21 of the photodiode 3a and that S22 of the photodiode 3b. Each of the photoelectric conversion region S21 of the photodiode 3a and that S22 of the photodiode 3b corresponds to a zone in which signal electric charges are generated through photoelectric conversion by causing light passing through the opening of the light shielding film 7 to be incident thereon. The openings of the light shielding film 7, which respectively correspond to the photodiodes 3a and 3b, are equal to each other in size. The photoelectric conversion regions S21 and S22 are substantially equal to each other in size.

The photoelectric conversion regions S21 and S22 are deviated in different orientations from the optical axis C of the microlens 24 to be symmetrical with respect to the optical axis C. In the case illustrated in FIG. 7, the photoelectric conversion regions S21 and S22 are deviated in the horizontal direction x to be symmetrical with respect to the optical axis C. In the case illustrated in FIG. 7, the photoelectric conversion regions S21 and S22 can be deviated in the vertical direction y to be symmetrical with respect to the optical axis C.

In the case of a plurality of pixels, the directions in the respective of which the photoelectric conversion regions S21 and S22 are deviated from the optical axis C are the same as each other. Consequently, phase difference AF detection can more accurately be performed. Such arrangement of the photoelectric conversion regions S21 and S22 is suited to a case where the size of each pixel is large, and where a plurality of photoelectric conversion regions can be formed corresponding to one microlens in each pixel.

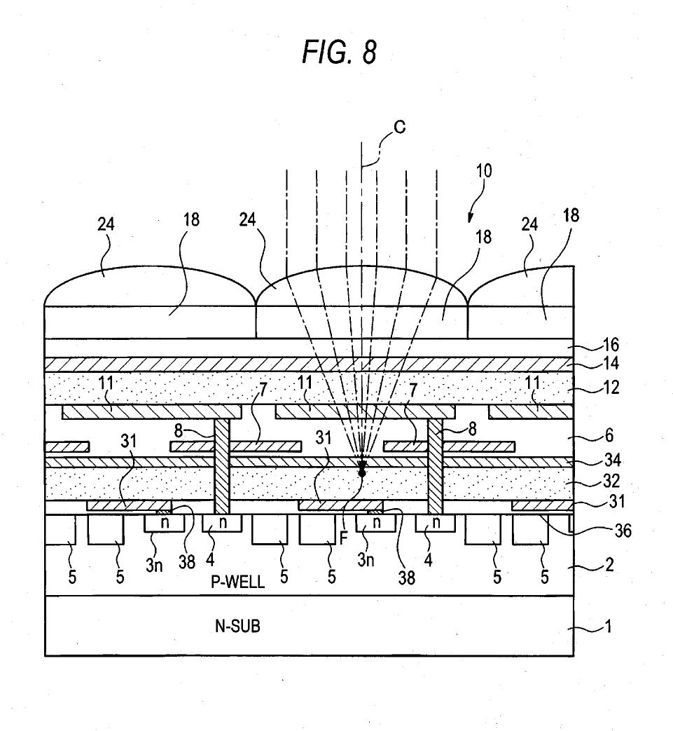

FIG. 8 is a view illustrating another example of the configuration of the imaging device. The configuration of the imaging device illustrated in FIG. 8 is nearly similar to that of the imaging device illustrated in FIG. 1. In this example, instead of providing embedded type photodiodes in the p-well layer 2 of the semiconductor substrate, a similar photoelectric conversion film 32 is provided below the photoelectric conversion film 12.

This imaging device 10 is such that an n-impurity diffused region 3n, n-impurity diffused region 4 and the signal reading portion 5 are provided in the p-well layer 2. The signal reading portions 5 are provided respectively corresponding to the impurity diffused region 3n and the impurity diffused region 4 one-by-one.

A transparent insulating film 36 is provided on the p-well layer 2. A plurality of pixel electrodes 31 are provided by being embedded in the top surface of an insulating film 36 to form a plane which is the same as the top surface thereof. The pixel electrodes 31 are configured by an electrode material, such as ITO, transparent to visible light.

A column-like contact portion 38 is provided in the insulating film 36 to extend in a thickness direction of the insulating film 36. The top part of each contact portion 38 is connected to an associated one of the pixel electrodes 31. The bottom part of each contact portion 38 is connected to an associated one of the impurity diffused regions 3n provided in the surface of the p-well layer 2 of the semiconductor substrate.

A photoelectric conversion film 32 configured by a single layer is formed to cover the top surface of each of the insulating film 36 and the pixel electrodes 31. The photoelectric conversion film 32 employs a photoelectric conversion material configured by an organic material and amorphous silicon, similarly to the photoelectric conversion film 12.

A counter electrode 34 configured by a single layer is provided on the photoelectric conversion film 32. The counter electrode 34 is configured by an electrode material, such as ITO, which is transparent to visible light, similarly to the pixel electrode 31.

A transparent insulating film 6 is provided on the counter electrode 34. Similarly to the imaging device illustrated in FIG. 1, a plurality of pixel electrodes 11, the light shielding films 7, and the contact portions 8 are formed in the insulating film 6. Each of the contact portions 8 is provided to penetrate through a region extending from the pixel electrodes 11 to the impurity diffused regions 4 of the p-well layer 2. Each of the pixel electrodes 11 is electrically conducted to an associated one of the impurity diffused region 4. A part of each of the contact portions 8, which penetrates through the associated counter electrode 34, is subjected to insulating processing so as not to electrically conduct the associated pixel electrode 11 and the impurity diffused region 4 in each pixel.

The photoelectric conversion film 12 configured by a single layer is provided to cover the top surface of the associated insulating film 6 and the associated pixel electrode 11. The counter electrode 14 configured by a single layer is provided on the photoelectric conversion film 12. In addition, similar to the example of the imaging device described above, the protection film 16, the color filter 18, and the microlens 24 are provided on the counter electrode 14 in this order.

When imaging is performed, a part of incident light is transmitted by the photoelectric conversion film 12 in each pixel. The transmitted light is received and subjected to photoelectric conversion by the photoelectric conversion film 32. Signal electric charges for phase difference AF are generated through photoelectric conversion by the photoelectric conversion film 32. The imaging device is such that the photoelectric conversion film 12 has sensitivity to the entire range of the visible light. Signal electric charges for a recording image can be generated by performing photoelectric conversion of most of the incident light by the photoelectric conversion film 12. In addition, the photoelectric conversion film 12 converts the transmitted light into signal electric charges for phase difference AF by photoelectric conversion. Thus, incident light can effectively be utilized.

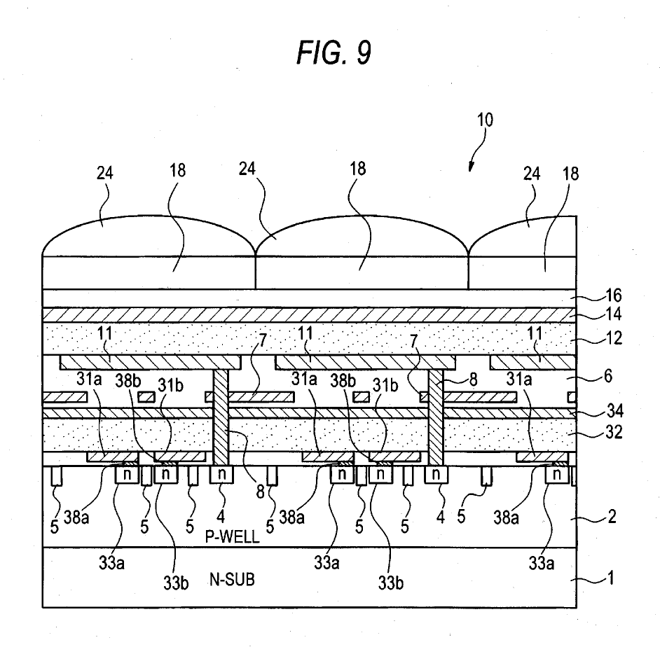

FIG. 9 is a cross-sectional view illustrating another example of the imaging device. The configuration of the imaging device is basically the same as that of the imaging device illustrated in FIG. 8.

Each pixel has two pixel electrodes 31a and 31b. The photoelectric conversion film 32 and the counter electrode 34, each of which is a single layer, are provided on the pixel electrodes 31a and 31b in this order. The insulating film 6 is formed on the counter electrode 34. A configuration including the pixel electrode 11 provided in the insulating film 6, and the photoelectric conversion film 12, the counter electrode 14, the protection layer 16, the color filter 18, and the microlens 24 provided on the insulating film 6 are the same of the configuration of the above imaging device. The light shielding film 7 provided in the insulating film 6 is formed so that the light shielding film 7 are opened at the upward positions respectively corresponding to the pixel electrodes 31a and 31b.

The photoelectric conversion film 32 is such that photoelectric conversion regions (assumed to be those S21 and S22) are formed between the counter electrode 34 and the pixel electrode 31a and between the counter electrode 34 and the pixel electrode 31b, respectively. The light shielding film 7 provided in the insulating film 6 is provided to cover a zone other than the photoelectric conversion regions.

The impurity diffused regions 4 and the signal reading portions 5 electrically connected to pixel electrodes 11 by the contact portions 8 are provided in the p-well layer 2 of the semiconductor substrate. An impurity diffused region 33a electrically connected to the pixel electrode 31a by a contact portion 38a and an impurity diffused region 33b electrically connected to the pixel electrode 31b by a contact portion 38b are formed in the p-well layer 2. The signal reading portions 5 are provided respectively corresponding to the impurity diffused regions 4, 33a and 33b one-by-one.

The positional relationship between the photoelectric conversion region provided on the pixel electrode 31a and that provided on the pixel electrode 31b in the photoelectric conversion film 32 is similar to that the photoelectric conversion region S21 of the photodiode 3a and that S22 of the photodiode 3b illustrated in FIG. 7. That is, the photoelectric conversion regions are nearly equal to each other and deviated in different directions to be symmetrical with respect to the optical axis C of the microlens 24. A plurality of pixels are disposed by being deviated in the horizontal direction x or the vertical direction y so that the photoelectric conversion regions are symmetrical with respect to the optical axis C.

If the photoelectric conversion regions of the photoelectric conversion films 32 of a plurality of pixels are arranged by being deviated to be symmetric with respect to the center of the optical axis, phase difference AF detection can more accurately be performed. Such arrangement is suited to a case that the size of each pixel is large and that a plurality of photoelectric conversion regions can be formed corresponding to the single microlens in each pixel.

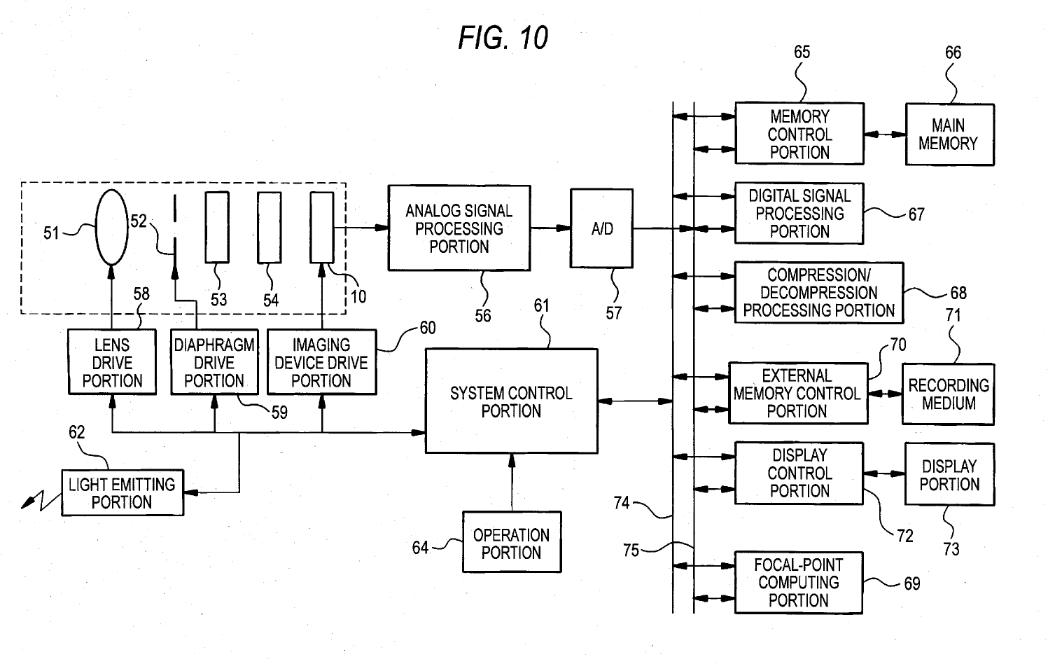

FIG. 10 is a view illustrating an imaging apparatus. In this example, the configuration of a digital camera is described hereinafter as that of the imaging apparatus by way of example. However, the imaging apparatus according to the invention can be a digital video camera or a camera-equipped mobile-phone.

The imaging apparatus is such that a lens group 51, an imaging device 10, a diaphragm 52 provided therebetween, an infrared cutoff filter 53, and an optical low-pass filter 54 are provided in an imaging portion. An element which is the same as the above imaging device can be used as the imaging device 10.

The lens group 51 includes a zoom lens for adjusting a zoom position, and a focus lens for adjusting a focus position, and the like.

A system control portion 61 for collectively controlling the entire electric control system of a digital camera is configured mainly by a processor that is operated by a predetermined program. The system control portion 61 controls a lens drive portion 58 to adjust a focus lens position and a zoom lens position of the lens group 51 and to adjust an exposure amount of the diaphragm 52 via a diaphragm drive portion 59.

The system control portion 61 drives the imaging device 10 via an imaging device drive portion 60 and outputs a subject image taken via the lens group 51 as an imaging signal. An instruction signal is input from a user through an operation portion 64 to the system control portion 61.

The electric control system of the digital camera further includes an analog signal processing portion 56 for performing analog signal processing, such as correlation double sampling processing, which is connected to an output of the imaging device 10, and an analog-to-digital (A/D) conversion circuit 57 for converting an imaging signal output from the analog signal processing portion 56 into a digital signal. These components are controlled by the system control portion 61.

The electric control system of the digital camera includes a main memory 66, a memory control portion 65 connected to the main memory 66, a digital signal processing portion 67 for generating image data by performing predetermine digital signal processing (e.g., interpolation computing, gamma correction computing, red-green-blue (RGB)/YCbCr (YC) conversion processing) on an imaging signal output from the A/D conversion circuit 57, a compression/decompression processing portion 68 for compressing image data generated by the digital signal processing portion 67 into data of Joint Photographic Experts Group (JPEG) format and decompressing compressed image data, an external memory control portion 70 to which a detachable recording medium 71 is connected, and a display control portion 72 to which a display portion 73 for displaying an image based on image data to be able to be stereoscopically viewed is connected. These components are interconnected to one another by a control bus 74 and a data bus 75 and controlled by instructions issued from the system control portion 61.

The display portion 73 is utilized as an image display portion for displaying a recording image. In addition, the display portion 73 is utilized as a graphical user interface (GUI) at various setting. When imaging is performed, an image taken by the imaging device 10 is continuously displayed in the display portion 73 as a live-view image. Accordingly, the display portion 73 is utilized as an electronic finder or the like.

The imaging apparatus includes a focal-point computing portion 69 for computing a phase difference based on signal electric charges for phase difference FA, which are detected by an imaging device. The focal-point computing portion 69 is connected to the control bus 74 and the data bus 75 and controlled by instructions issued from the system control portion 61.

When imaging is performed, the imaging apparatus reads, from the imaging device, signal electric charge for phase difference AF. The focal-point computing portion 69 compares image data read from a first pixel group with image data read from a second pixel group and detects a phase difference, based on the signal electric charges for phase difference AF. Then, the focal-point computing portion 69 calculates a necessary lens movement distance by which a lens is moved to bring the imaging device into a focused state according to the phase difference. The system control portion 61 drive-controls the lens drive portion 58, based on signals from the focal-point computing portion 69, to perform focal-point adjustment.

In the imaging apparatus, it is not always necessary to read signal electric charges for phase difference AF, differently from signal electric charges needs always reading. For example, while a recording image generated in the first photoelectric conversion portion is subjected to live-view image display at a predetermined frame rate (e.g., 30 frames per second (fps)), the second photoelectric conversion portion can read signal electric charges for phase difference AF, at a frame rate (e.g., 10 fps) lower than the frame rate at which the live-view image display is performed. Thus, an exposure time of signal electric charges for phase difference AF, which are read by the second photoelectric conversion portion, can be assured.

In the above example, the imaging device is such that each pixel is provided with the color filter 18. Thus, signal electric charges for a color recording image are obtained. Consequently, the imaging device can be configured without a color filter to acquire signal electric charges for a monochrome recording image.

The present specification includes the following items.

(1) An imaging device includes a plurality of two-dimensionally-arranged pixels each of which generates signal electric charges by performing photoelectric conversion of incident light. Each of the pixels includes a microlens, a first photoelectric conversion portion, a second photoelectric conversion portion and a signal reading portion. The microlens collects incident light. The first photoelectric conversion portion is between the microlens and a focal point of the microlens. The second photoelectric conversion portion is at a position being different from a position of the focal point on a plane which is parallel to an imaging plane and which contains the focal point. The second photoelectric conversion portion has a photoelectric conversion region deviated from an optical axis of the microlens in a direction of the imaging plane. The signal reading portion reads a signal electric charge. The plurality of pixels include a first pixel group and a second pixel group. The photoelectric conversion region of the second photoelectric conversion portion is deviated from the optical axis in the direction of the imaging plane in the first pixel group. The photoelectric conversion region of the second photoelectric conversion portion is deviated from the optical axis in the direction of the imaging plane to be opposite to the first pixel group in the second pixel group.

(2) The imaging device according to (1), the photoelectric conversion region of the second photoelectric conversion portion are deviated from the optical axis in different orientations of a horizontal direction of the imaging plane in the first and second pixel groups respectively.

(3) The imaging device according to (1), the photoelectric conversion region of the second photoelectric conversion portion are deviated from the optical axis in different orientations of a vertical direction of the imaging plane in the first and second pixel groups respectively.

(4) The imaging device according to any one of (1) to (3), color filters are provided between the microlens and the first photoelectric conversion portion of each pixel. The color filters are arranged in a Bayer array. At least a part of pixels includes a G-color filter transmitting light of a green wavelength range in the first and second pixel groups respectively.

(5) The imaging device according to (4), the plurality of pixels are arranged like a square lattice. Each pixel having a G-color filter of the first pixel group and each pixel having a G-color filter of the second pixel group are arranged not to adjoin each other.

(6) The imaging device according any one of (1) to (5), the pixel groups include a third pixel group and a fourth pixel group configured so that the photoelectric conversion region of the second photoelectric conversion portion of each pixel of the third pixel group and the photoelectric conversion region of the second photoelectric conversion portion of each pixel of the fourth pixel group are deviated from the optical axis in different directions of the imaging plane. A direction in which the photoelectric conversion region of the second photoelectric conversion portion are deviated from the optical axis in the third and forth pixel group is perpendicular to a direction in which the photoelectric conversion region of the second photoelectric conversion portion are deviated from the optical axis in the first and second pixel group.

(7) The imaging device according to any one of (1) to (6), a light shielding film is provided between the first photoelectric conversion portion and the second photoelectric conversion portion to cover a zone of the second photoelectric conversion portion, which is other than the photoelectric conversion region thereof.

(8) An imaging device includes a plurality of two-dimensionally-arranged pixels each of which generates signal electric charges by performing photoelectric conversion of incident light. Each of the pixels includes a microlens, a first photoelectric conversion portion, a second photoelectric conversion portion and a signal reading portion. The microlens collects incident light. The first photoelectric conversion portion is between the microlens and a focal point of the microlens. The second photoelectric conversion portion is at a position being different from a position of the focal point on a plane which is parallel to an imaging plane and which contains the focal point. The signal reading portion reads a signal electric charge. The second photoelectric conversion portion has a plurality of photoelectric conversion regions formed to be deviated from the optical axis in different orientations on the imaging plane to be symmetric with respect to a center of the optical axis of the microlens.

(9) The imaging device according to (8), directions in which the photoelectric conversion regions of the second photoelectric conversion portions of the plurality of pixels are respectively deviated from the optical axis are a same direction.

(10) The imaging device according to (9), color filters are provided between the microlens and the first photoelectric conversion portion of each pixel and arranged in a Bayer array.

(11) The imaging device according to any one of (1) to (10), the first photoelectric conversion portion is a photoelectric conversion film including an organic material. The second photoelectric conversion portion is a photodiode provided in a semiconductor substrate.

(12) The imaging device according to any one of (1) to (10), each of the first photoelectric conversion portion and the second photoelectric conversion portion is a photoelectric conversion film including an organic material.

(13) An imaging apparatus includes the imaging device according to any one of (1) to (12) and a unit. The unit generates a recording image based on a signal electric charge obtained from the first photoelectric conversion portion. The unit detects a phase difference and computes a focal point based on a signal electric charge obtained from the second photoelectric conversion portion.

The imaging device according to the invention is suited to a digital video camera and a digital camera. In addition, the imaging device can be applied to imaging devices mounted on endoscopes and portable terminals.

What is claimed is:

1. An imaging device comprising:
a plurality of two-dimensionally-arranged pixels each of which generates signal electric charges by performing photoelectric conversion of incident light,
wherein each of the pixels includes
a microlens configured to collect incident light,
a first photoelectric conversion portion provided between the microlens and a focal point of the microlens,
a second photoelectric conversion portion that is provided at a position being different from a position of the focal point on a plane which is parallel to an imaging plane and which contains the focal point, and that has a photoelectric conversion region deviated from an optical axis of the microlens in a direction of the imaging plane, and
a signal reading portion configured to read a signal electric charge, and
wherein the plurality of pixels include a first pixel group and a second pixel group, the first pixel group in which the photoelectric conversion region of the second photoelectric conversion portion is deviated from the optical axis in the direction of the imaging plane, the second pixel group in which the photoelectric conversion region of the second photoelectric conversion portion is deviated from the optical axis in the direction of the imaging plane to be opposite to the first pixel group.

2. The imaging device according to claim 1,
wherein the photoelectric conversion region of the second photoelectric conversion portion are deviated from the optical axis in different orientations of a horizontal direction of the imaging plane in the first and second pixel groups respectively.

3. The imaging device according to claim 1,
wherein the photoelectric conversion region of the second photoelectric conversion portion are deviated from the optical axis in different orientations of a vertical direction of the imaging plane in the first and second pixel groups respectively.

4. The imaging device according to claim 1,
wherein color filters are provided between the microlens and the first photoelectric conversion portion of each pixel,
wherein the color filters are arranged in a Bayer array, and
wherein at least a part of pixels includes a G-color filter transmitting light of a green wavelength range in the first and second pixel groups respectively.

5. The imaging device according to claim 4,
wherein the plurality of pixels are arranged like a square lattice, and
wherein each pixel having a G-color filter of the first pixel group and each pixel having a G-color filter of the second pixel group are arranged not to adjoin each other.

6. The imaging device according to claim 1,
wherein the pixel groups include a third pixel group and a fourth pixel group configured so that the photoelectric conversion region of the second photoelectric conversion portion of each pixel of the third pixel group and the photoelectric conversion region of the second photoelectric conversion portion of each pixel of the fourth pixel group are deviated from the optical axis in different directions of the imaging plane, and
wherein a direction in which the photoelectric conversion region of the second photoelectric conversion portion are deviated from the optical axis in the third and forth pixel group is perpendicular to a direction in which the photoelectric conversion region of the second photoelectric conversion portion are deviated from the optical axis in the first and second pixel group.

7. The imaging device according to claim 1,
wherein a light shielding film is provided between the first photoelectric conversion portion and the second photoelectric conversion portion to cover a zone of the second photoelectric conversion portion, which is other than the photoelectric conversion region thereof.

8. An imaging device comprising:
a plurality of two-dimensionally-arranged pixels each of which generates signal electric charges by performing photoelectric conversion of incident light,
wherein each of the pixels includes
a microlens configured to collect incident light,
a first photoelectric conversion portion provided between the microlens and a focal point of the microlens,
a second photoelectric conversion portion that is provided at a position being different from a position of the focal point on a plane which is parallel to an imaging plane and which contains the focal point, and
a signal reading portion configured to read a signal electric charge, and
wherein the second photoelectric conversion portion has a plurality of photoelectric conversion regions formed to be deviated from the optical axis in different orientations on the imaging plane to be symmetric with respect to a center of the optical axis of the microlens.

9. The imaging device according to claim 8,
wherein directions in which the photoelectric conversion regions of the second photoelectric conversion portions of the plurality of pixels are respectively deviated from the optical axis are a same direction.

10. The imaging device according to claim 9,
wherein color filters are provided between the microlens and the first photoelectric conversion portion of each pixel and arranged in a Bayer array.

11. The imaging device according to claim 1,
wherein the first photoelectric conversion portion is a photoelectric conversion film including an organic material, and
wherein the second photoelectric conversion portion is a photodiode provided in a semiconductor substrate.

12. The imaging device according to claim 1,
wherein each of the first photoelectric conversion portion and the second photoelectric conversion portion is a photoelectric conversion film including an organic material.

13. An imaging apparatus comprising:
the imaging device according to claim 1; and
a unit that generates a recording image based on a signal electric charge obtained from the first photoelectric conversion portion, that detects a phase difference, and that computes a focal point based on a signal electric charge obtained from the second photoelectric conversion portion.
